(19) United States
(12) Patent Application Publication
(10) Pub. No.: US 2010/0252852 A1
(43) Pub. Date: Oct. 7, 2010

(54) COOLING BLOCK ASSEMBLY AND LED INCLUDING THE COOLING BLOCK

(76) Inventors: Chih-Hung WEI, Tu Cheng City (TW); Chih-Yang HSU, Tu Cheng City (TW); Ming-Chang Wu, Tu Cheng City (TW); Ming-Yu HSU, Tu Cheng City (TW); Ming-Te KU, Tu Cheng (TW); Chih-Lung WU, Tu Cheng City (TW)

Correspondence Address: HDLS Patent & Trademark Services, P.O. BOX 220746, CHANTILLY, VA, 20153-0746, US

(21) Appl. No.: 12/418,773

(22) Filed: Apr. 6, 2009

(51) Int. Cl. H01L 33/00

(52) U.S. Cl. 257/99; 361/714; 257/E33.056

(57) ABSTRACT

An LED includes a cooling block, an LED chip, two insulating layers, two electrically conductive layers and two gold wires. According to the invention, two open trenches are arranged by opening on the cooling block; the LED chip is fixed on a surface of the cooling block; the insulating layers are plated on inner walls of the trenches; the electrically conductive layers are plated on the insulating layers and are insulated from the cooling block; the gold wires are electrically conducted to the electrically conductive layers and the LED chip; since the insulating layers are only plated on parts, where the cooling block contacts the electrically conductive layers, the other parts of the cooling block are exposed, such that the cooling area is increased and the cooling performance is promoted; in addition, the invention is further to provide a cooling block assembly constituted by these cooling blocks.

### BACKGROUND OF THE INVENTION

1. Field of the Invention

The present invention in general relates to an LED, in particular, to a cooling block assembly and an LED including the cooling block.

2. Description of Prior Art

When LED emits light, since its chip generates a large amount of heat, if the heat cannot be removed immediately, then the lighting performance and the lifetime of the LED will be lowered down and reduced, so a general LED usually has a cooling structure. Please refer to FIG. 1, which is an illustration of an LED according to a prior art. The prior LED 1a usually includes a cooling block 10a, an LED chip 20a, a plurality of insulating layers 30a, a plurality of electrically conductive blocks 40a and a plurality of gold wires 50a.

Originally, the cooling block 10a and the electrically conductive block 40a are of one metal block that is etched into gaps by an etching manner, so this metal block is divided into a cooling block 10a and two electrically conductive blocks 40a located at two sides of the cooling block 10a. In the meantime, the LED chip 20a is connected by pasting on the cooling block 10a. The insulating layers 30a are formed by injecting insulating materials into the gaps between the cooling block 10a and the electrically conductive blocks 40a, such that the cooling block 10a and the electrically conductive layers 40a are insulated to each other. Finally, the gold wires 50a are provided for connecting the LED chip 20a and the electrically conductive layers 40a.

However, this kind of prior LED 1a still has a drawback, in terms of practical usage. Since the cooling block 10a and the electrically conductive blocks 40 are divided from a metal block, the volume at the center of the cooling block 10a is not large enough, so that the heat generated from the LED chip 20a can not be dissipated by the cooling block 10a immediately. Thereby, the lighting efficiency is lowered down and the lifetime is shortened, because the temperature of the LED chip 20a is too high.

In addition, please refer to FIG. 2, which is an illustration of an LED according to another prior art. This kind of prior LED 1b also includes a cooling block 10b, an LED chip 20b, a plurality of insulating layers 30b, a plurality of electrically conductive layers 40b and a gold wire 50b.

The manufacturing process of the LED 1b is described as the following. Firstly, a plurality of penetrating holes 11b shown as closed figurations are arranged on the cooling block 10b; then, the insulating layers 30b cover the outer surfaces of the cooling block 10b and the inner surfaces of the penetrating holes 11b; next, the electrically conductive layers 40b are plated over the outer surfaces of the cooling block 10b and the insulating layers 30b plated on the inner surfaces of the penetrating holes 11b, in which the electrically conductive layers 40b plated on the outer surfaces of the cooling block 10b are interspaced to each other; finally, the LED chip 20b is attached on one electrically conductive layer 40b and the gold wire 40b connects the LED chip 20b to another electrically conductive layer 40b.

However, the structure of this kind of prior LED 2b still possesses a number of shortcomings, in terms of practical usage. Firstly, since the outer surfaces of the cooling block 10b are all covered by the insulating layers 30b, it is impossible for the cooling block 10b to develop cooling function thoroughly. In addition, since the penetrating holes 11b are shown as closed configurations, when the inner surfaces of the penetrating holes 11b are plated with the insulating layers 30b and the electrically conductive layers 40b, the machining processes are more tedious and time consuming.

Therefore, how to improve and solve the aforementioned problems is an issue intended to be addressed by the inventor.

Accordingly, after a substantially devoted study, in cooperation with the application of relatively academic principles, the inventor has finally proposed the present invention that is designed reasonably to possess the capability to improve the drawbacks of the prior arts significantly.

### SUMMARY OF THE INVENTION

The invention is mainly to provide a cooling block assembly and an LED including the cooling block. Because the insulating layers are only plated on the parts where the cooling block contacts the electrically conductive layers, the other parts of the cooling block are still exposed, thereby, increasing the cooling area and promoting the cooling performance.

Secondly, the invention is to provide an LED including a cooling block, an LED chip, two insulating layers, two electrically conductive layers and two gold wires. According to the invention, two open trenches are arranged by opening on the cooling block; the LED chip is fixed on one surface of the cooling block; the insulating layers are plated on the inner walls of the trenches; the electrically conductive layers are plated on the insulating layers and are insulated from the cooling block; the gold wires are electrically conducted to the electrically conductive layers and the LED chip.

Thirdly, the invention is to provide a cooling block assembly, including a plate body constituted by a plurality of cooling blocks. A plurality of first intended-to-be-cut lines interspaced in parallel to each other and a plurality of second intended-to-be-cut lines vertically intersected to the first intended-to-be-cut lines are arranged on the plate body. Any one of the cooling blocks is formed by an enclosure of at least one of the first intended-to-be-cut lines and at least one of the second intended-to-be-cut lines. Furthermore, a plurality of penetrating holes are arranged by opening on the first intended-to-be-cut lines and are shown as an array distribution.

Compared to the prior arts, the advantageous functions of the invention are that the shortcoming of small cooling area can be solved, because the insulating layers are only plated on the trenches instead on the whole outer surfaces of the cooling block, thereby, increasing the cooling area provided by the cooling block and promoting the cooling performance; in addition, by the structure of the open trenches, the materials consumed by the cooling block can be saved, when arranging and opening the open trenches; finally, the structure of the open trench is more easily machined during the manufacturing process of plating.

### BRIEF DESCRIPTION OF DRAWING

The features of the invention believed to be novel are set forth with particularity in the appended claims. The invention itself, however, may be best understood by reference to the following detailed description of the invention, which describes several exemplary embodiments of the invention, taken in conjunction with the accompanying drawings, in which:

FIG. 1 is an illustration of a prior LED;

FIG. 2 is an illustration of another prior LED;

FIG. 3 is a perspective outer view of an LED of the invention;

FIG. 4 is a perspective outer view of a cooling block assembly of the invention;

FIG. 5 is a perspective outer view of a cooling block of the invention;

FIG. 6 is a cross-sectional view made along the cross-sectional line “6-6” in FIG. 5;

FIG. 7 is a packaging illustration (1) of an LED of the invention;

FIG. 8 is a packaging illustration (2) of an LED of the invention;

FIG. 9 is a packaging illustration (3) of an LED of the invention;

FIG. 10 is a packaging illustration (4) of an LED of the invention;

FIG. 11 is a perspective outer view of a cooling block assembly of another embodiment of the invention; and

FIG. 12 is a perspective outer view of an LED of another embodiment of the invention.

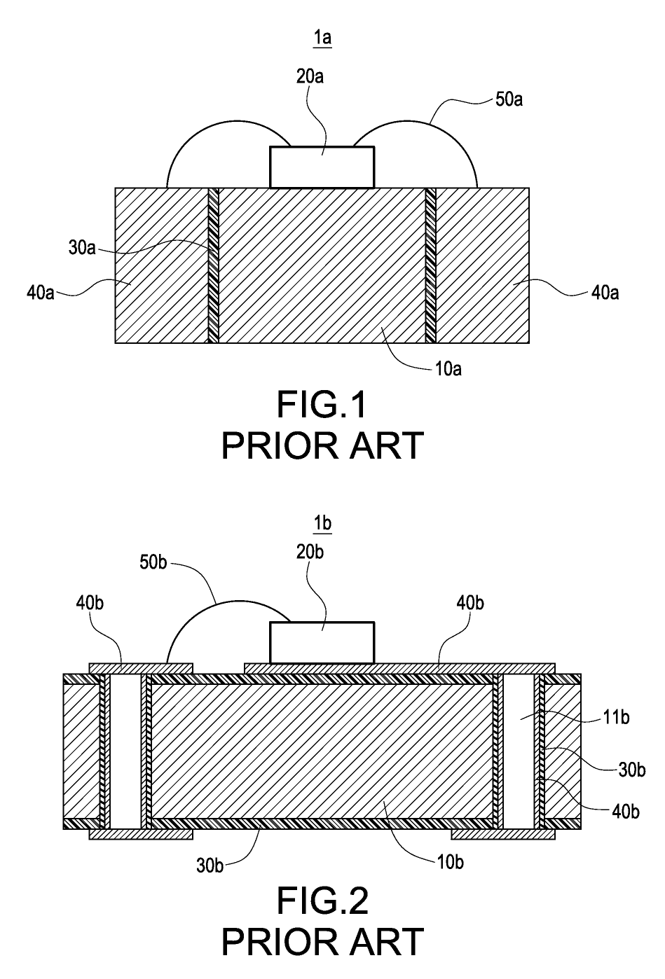

### DETAILED DESCRIPTION OF THE INVENTION

In cooperation with attached drawings, the technical contents and detailed description of the present invention are described thereinafter according to a number of preferable embodiments, not used to limit its executing scope. Any equivalent variation and modification made according to appended claims is all covered by the claims claimed by the present invention.

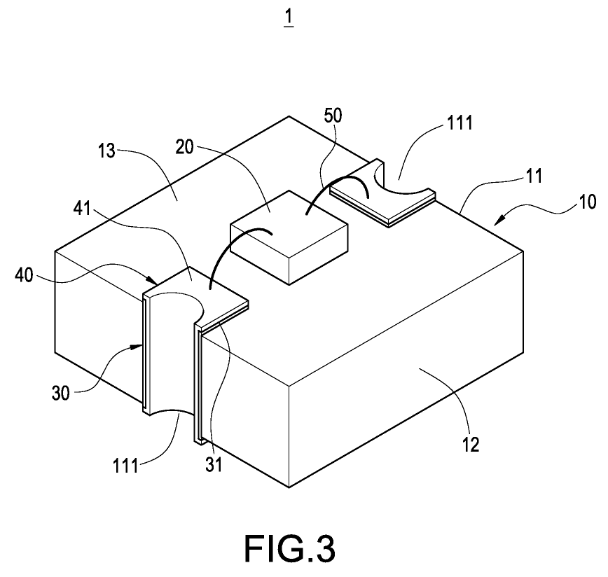

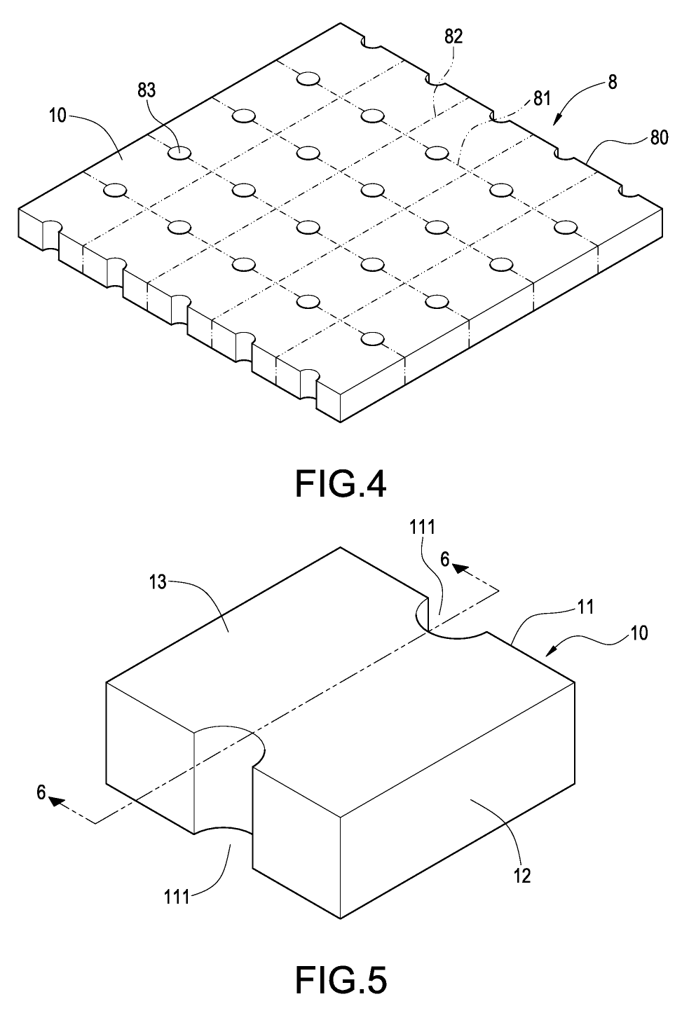

Please refer to FIG. 3 through FIG. 5, which respectively are a perspective outer view of an LED of the invention, a perspective outer view of a cooling block assembly of the invention and a perspective outer view of a cooling block of the invention, in which the invention is to provide an LED 1 including cooling block, including a cooling block 10, an LED chip 20, two insulating layers 30, two electrically conductive layers 40 and two gold lines 50.

According to an embodiment of the invention, two open trenches 111 are arranged at two corresponding sides of the cooling block 10 shown as a rectangular shape, at two inter-parallel sides of which the open trenches 111 are arranged. By so doing, the two sides are defined as a first side 11 respectively, while another two sides of the cooling block 10 are defined as a second side 12. Besides, the cooling block 10 also has a surface 13.

In addition, according to this embodiment, the configuration of the open trench 111 is shown as a semi-circular shape, which is easier on a manufacturing process and saves machining materials. If a circular penetrating hole shown as a closed configuration is arranged by opening on the cooling block 10, then more materials will be removed, which causes a waste.

Furthermore, this kind of open trench 111 is more convenient in terms of plating process because, during a plating process, another material is usually only plated on the open trench 111 instead on the whole cooling block 10. Besides, there is some degree of difficulty for machining a closed penetrating hole in terms of plating process, while the open trench 111 is easier to be machined.

Finally, the operating area of the open trench 111 is larger than that of the closed penetrating hole, so it is much easier in machining the open trench 111. The open trench 111 shown as a semi-circular configuration is only an embodiment of the invention. Namely, the shape of the open trench 111 is not limited to a semi-circular shape only. The cooling block 10 is made of metallic materials with excellent thermal and electric conductivities. The material is usually a copper, but not limited to this material only.

The LED chip 20 is fixed onto the surface 13 of the cooling block 10. In this embodiment, the LED chip 20 is attached to a central position on the top face of the cooling block 10. The LED chip 20 is a cuboid, however, not limited to this configuration only.

The insulating layers 30 are respectively plated on the inner walls of the trenches 111, while the electrically conductive layers 40 are respectively plated on the insulating layers 30 and shown as an insulating relationship with the cooling block 10. On the other hand, the gold wires 50 are electrically conducted to the electrically conductive layer 40 and the LED chip 20 respectively.

The insulating layer 30 further includes an extending section 31, which is attached on the surface 13 of the cooling block 10. In this case, the electrically conductive layer 40 further includes a welding section 41, which is pasted upon the extending section 31 for a provision of a welding end for the gold wire 50. In addition, the insulating layer 30 further includes another extending section 31 and another welding section 41 that is attached on a bottom surface of the cooling block 10, making the cooling block 10 more conveniently connected to other elements in a welding manner.

In addition, the invention is also to provide a cooling block assembly 8 for LED. The cooling block assembly 8 includes a plate body 80 constituted by a plurality of cooling blocks 10. A plurality of first intended-to-be-cut lines 81 interspaced in parallel and a plurality of second intended-to-be-cut lines 82 vertically intersected to the first intended-to-be-cut lines 81 are arranged on the plate body 80. Any one of the cooling blocks 10 is enclosed by at least one of the first intended-to-be-cut lines 81 and at least one of the second intended-to-be-cut lines 82. In the meantime, a plurality of penetrating holes 83 are arranged by opening on the first intended-to-be-cut lines 81 and shown as an array distribution. The shapes of the penetrating holes 83 are all a circle, however, not limited to this configuration only. By so doing, the second intended-to-be-cut lines 82 are formed between any two adjacent penetrating holes 83.

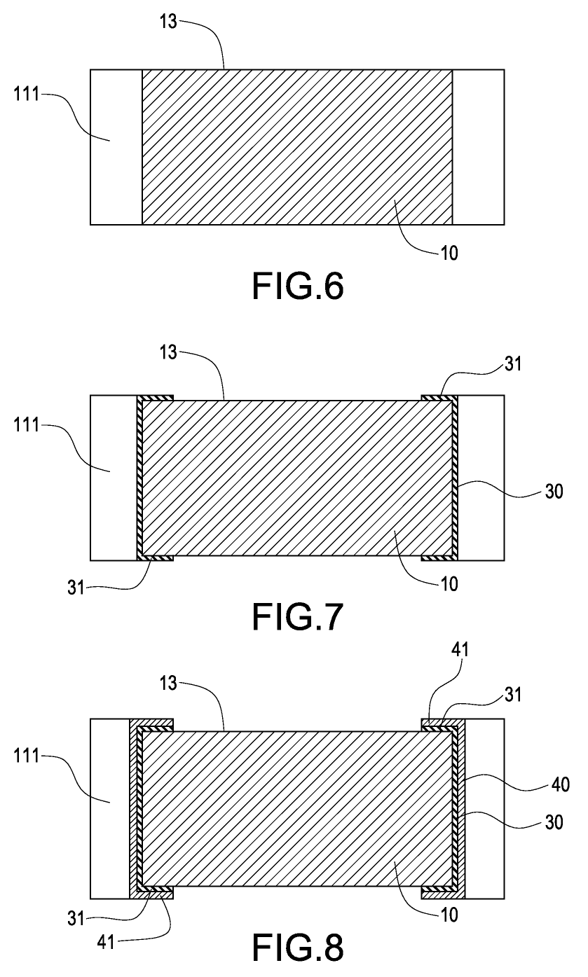

Please refer to FIG. 6 through FIG. 8, which respectively are a cross-sectional view made along the cross-sectional line “6-6” in FIG. 5, a packaging illustration (1) of an LED of the invention and a packaging illustration (2) of an LED of the invention. The packaging process of the LED 1 including cooling block according to the present invention is described thereinafter. Firstly, an insulating layer 30 is plated over the open trench 111 of the cooling block 10, in this case, only over the inner wall of the open trench 111 instead over the outer surfaces of the entire cooling block 10, so the cooling area of the cooling block 10 may increase and the cooling performance of the cooling block 10 is promoted. Secondly, the electrically conductive layer 40 is plated over the insulating layer 30.

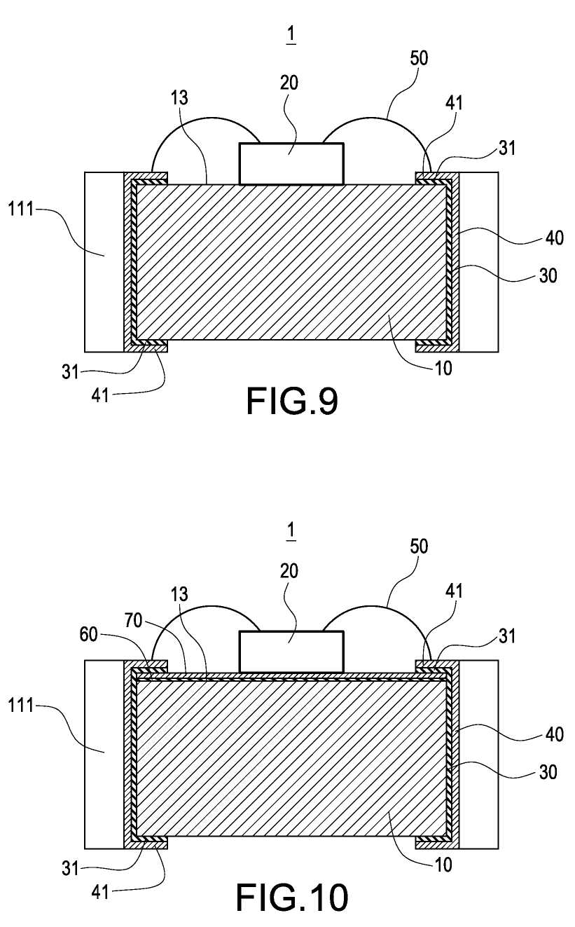

Please refer to FIG. 9 and FIG. 10, which respectively are a packaging illustration (3) and a packaging illustration (4) of an LED of the invention. In next step, the LED chip 20 is fixed onto the top face of the cooling block 10 and the gold wire 50 is electrically conducted the LED chip 20 and the electrically conductive layer 40. Finally, a media layer 60 and a reflecting layer 70 are plated on the outer surface of the cooling block 10, on which the LED chip 20 is located.

The purpose of plating the media layer 60 is for making the reflecting layer 70 able to be plated on the cooling block 10. Because the copper can not be directly plated on any metallic material, a media layer 60 has to be plated on the cooling block 10 in advance, such that it is then possible for the reflecting layer 70 able to be plated on the cooling block 10. The function of the reflecting layer 70 is to make a maximal usage of the light emitted from the LED chip 20, thereby, promoting the lighting efficiency. In this case, the reflecting layer 70 may be made of materials of gold or silver.

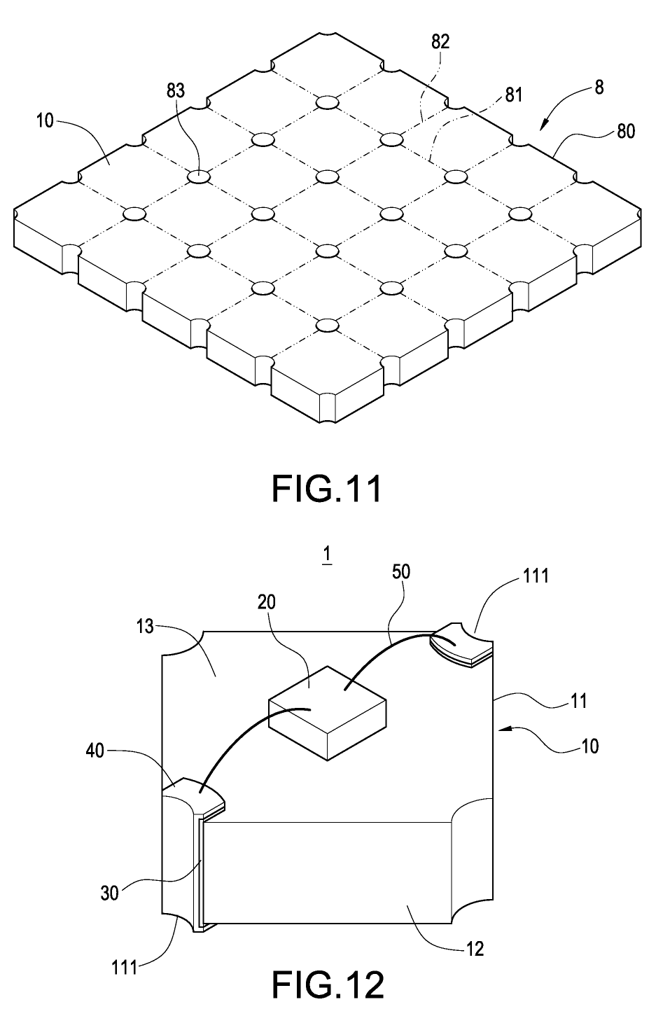

Please refer to FIG. 11 and FIG. 12, which respectively are a perspective outer view of a cooling block assembly according to another embodiment of the invention and a perspective outer view of an LED according to another embodiment of the invention. In these embodiments, the invention provides another manner for cutting the cooling block assembly 8, in which the second intended-to-be-cut lines 82 pass through the penetrating holes 83.

The cooling block 10 has two first sides 11 in parallel to each other and two second sides 12 also in parallel to each other. By so doing, the open trench 111 is arranged at the intersection of the first side 11 and the second side 12. In other words, these two open trenches 111 will be arranged at two opposite angles, while the configuration of the open trench 111 is shown as a quarter of circle, however, not limited to these position and shape only.

Summarizing aforementioned description, the invention is an indispensably novel structure for a compressor indeed, which may positively reach the expected usage objective for solving the drawbacks of the prior arts, and which extremely possesses the innovation and progressiveness to completely fulfill the applying merits of new type patent, according to which the invention is thereby applied. Please examine the application carefully and grant it as a formal patent for protecting the rights of the inventor.

However, the aforementioned description is only a number of preferable embodiments according to the present invention, not used to limit the patent scope of the invention, so equivalently structural variation made to the contents of the present invention, for example, description and drawings, is all covered by the claims claimed thereinafter.

What is claimed is:

1. An LED, including:
a cooling block, on which two open trenches are arranged;
an LED chip, which is fixed on a surface of the cooling block;
two insulating layers, which are respectively plated on inner walls of the trenches;
two electrically conductive layers, which are respectively plated on the insulating layers and are insulated from the cooling block; and
two gold wires, which are respectively electrically conducted to the electrically conductive layers and the LED chip.

2. The LED including cooling block according to claim 1, wherein the two trenches are located at two corresponding sides of the cooling block.

3. The LED including cooling block according to claim 1, wherein the insulating layer further includes an extending section that is pasted onto the surface of the cooling block.

4. The LED including cooling block according to claim 3, wherein the electrically conductive layer further includes a welding section that is pasted onto the extending section for a provision of a welding end for the gold wire.

5. The LED including cooling block according to claim 1, wherein the cooling block is shown as a rectangular shape, and wherein the trenches are arranged by opening at two sides of the cooling block, which are in parallel to each other.

6. The LED including cooling block according to claim 5, wherein the trench is shown as a semi-circle.

7. The LED including cooling block according to claim 1, wherein the cooling block is shown as a rectangular shape and the trenches are arranged by opening at two opposite angles of the cooling block.

8. The LED including cooling block according to claim 7, wherein the trench is shown as a quarter of a circle.

9. The LED including cooling block according to claim 1, further including a media layer plated over the surface of the cooling block and a reflecting layer plated over the media layer.

10. A cooling block assembly including a plate body, which is constituted by a plurality of cooling blocks, and arranged on which are a plurality of first intended-to-be-cut lines interspaced in parallel to each other and a plurality of second intended-to-be-cut lines vertically intersected to the first intended-to-be-cut lines; any one of the cooling blocks being formed by an enclosure of at least one of the first intended-to-be-cut lines and at least one of the second intended-to-be-cut lines; a plurality of penetrating holes being arranged by opening on the first intended-to-be-cut lines and being shown as an array distribution.

11. The cooling block assembly according to claim 10, wherein the second intended-to-be-cut line is formed between any two adjacent penetrating holes.

12. The cooling block assembly according to claim 10, wherein the second intended-to-be-cut line passes through the penetrating holes.
